(19) United States
(12) Patent Application Publication
(10) Pub. No.: US 2008/0061358 A1
(43) Pub. Date: Mar. 13, 2008

(54) Method of reducing memory cell size for non-volatile memory device

(75) Inventor: David S. Choi, Cupertino, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Embedded Memory, Inc., Santa Clara, CA (US)

(21) Appl. No.: 11/713,548

(22) Filed: Mar. 1, 2007

Related U.S. Application Data
(60) Provisional application No. 60/777,987, filed on Mar. 2, 2006.

(30) Foreign Application Priority Data
Apr. 14, 2006 (KR) 10-2006-0033917

(51) Int. Cl. H01L 27/108; H01L 21/8242

(52) U.S. Cl. 257/319; 438/266; 257/E27.084; 257/E21.646

(57) ABSTRACT

In accordance with the present invention, a new method, its structure and manufacturing method is proposed to reduce memory cell size about the half of the conventional method for a non-volatile NAND Flash cell. The control gates in a string of the NAND Flash cell array is formed as the combination of the drawn control gate and the self-aligned control gate by using a spacer method. The source and drain of a NAND cell is defined as the low doped region underneath the spacer.

### CROSS-REFERENCES TO RELATED APPLICATIONS

The present application claims benefit of US application number US60/777,987, filed on Mar. 2, 2006, entitled “Method Of Reducing Memory Cell Size For Non-volatile memory Device”, the content of which is incorporated herein by reference in its entirety.

The present application also claims benefit of Korean application number 10 -2006-0033917, filed on Apr. 14, 2006, entitled “Method Of Reducing Memory Cell Size For Non-volatile memory Device and its manufacturing”, the content of which is incorporated herein by reference in its entirety.

### BACKGROUND OF THE INVENTION

The present invention relates to semiconductor integrated circuits technology. More particularly, the invention provides a method in semiconductor memory that has reduced memory cell size for a non-volatile memory cells by making a smaller distance between the device. Although the invention has been applied to a single integrated circuit device in a memory application, there can be other alternatives, variations, and modifications. For example, the invention can be applied to other memory cell size reduction application, including embedded memory applications for those with logic or micro circuits, and the like.

Semiconductor memory devices have been widely used in electronic systems to store data. Non-volatile semiconductor memory devices are also well known. A non-volatile semiconductor memory device, such as flash Erasable Programmable Read Only Memory (Flash EPROM), Electrically Erasable Programmable Read Only Memory (EEPROM) or, Metal Nitride Oxide Semiconductor (MNOS), retains its charge even after the power applied thereto is turned off. Therefore, where loss of data due to power failure or termination is unacceptable, a non-volatile memory is used to store the data.

There are generally two types of non-volatile Flash EEPROM memories. The first is non-volatile memory NOR type Flash and the other is NAND type Flash.

A NAND type Flash has a set of memory cells string or blocks. Each set of string or block is constructed by typically either 16 cells or 32 cells serially connecting a plurality of memory cells, and is integrated with high density. A plurality of memory cells are serially connected with the adjacent two of the memory cells commonly using the source/drain to form a NAND cell. The NAND cells, a set of string, are arranged in a matrix form to construct the memory cell array.

The growth in demand for NAND Flash, such as cellular phones or portable memory storage using USB, personal organizers, has brought to the fore the need to reduce the cell size, in return to reduce cost without degrading the performance and the reliability. The occupancy of the memory cell array is dominant element in the total chip area. Therefore, reducing the memory cell size without sacrificing reliability and performance is the key for the reduction of cost.

As merely an example, FIG. 1 is a transistor schematic diagram of a prior art NAND Flash core architecture. Each sector has 512 single NAND strings or core blocks. A single string NAND cells has two select transistors, the source and drain, and 32 word line ( or control gate) unit cells, W/L ₀, W/L ₁, W/L ₂, . . . W/L ₃₁ with source and drain.

As merely an example, FIG. 2 is a cross sectional view of two NAND cells structure in prior art having source/drain, tunnel oxide 42, floating gate 44, the coupling insulator 46, and the control gate (word line of NAND cell) 50.

As merely an example, FIG. 3a is a cross sectional view of single string of NAND structure having ground line (SRC), select transistor for source (GSL), 32 flash cells connected serially through source/drain, select transistor for drain (SSL), and bit line (BL). As merely an example, FIG. 3b is a layout view of single string of NAND structure having ground line (SRC), select transistor for source (GSL), 32 flash cells connected serially through source/drain, select transistor for drain (SSL), and bit line (BL).

As merely an example shown in FIG. 3a and FIG. 3b, a single string NAND cell of 32 cells has the 32 space between each word line of 32 flash cells and the space is determined by the technology used. For an example, the space is at least 90 nm for the 90 nm technology and the word line width is 90 nm.

As merely an example, a new method of forming a new single string NAND cell of 32 for a given width is shown in shown in FIG. 4, FIG. 5 and FIG. 4b

While the invention is described in conjunction with the preferred embodiments, this description is not intended in any way as a limitation to the scope of the invention. Modifications, changes, and variations, which are apparent to those skilled in the art can be made in the arrangement, operation and details of construction of the invention disclosed herein without departing from the spirit and scope of the invention.

### BRIEF SUMMARY OF THE INVENTION

In accordance with the present invention, a method of forming a smaller cell size of NAND flash by reducing the space between the word lines ( flash gate) through the combination of a conventional photo-mask step for making a word line and a self-aligned word line for a non-volatile semiconductor device, includes, in part, the steps of: forming isolation regions either through the conventional locos isolation or trench isolation in the semiconductor substrate, forming a first well between the two isolation regions, forming a second well between the two isolation regions and above the first well to define a body region, forming a different doping concentration by ion implantation to adjust Vt in the wells, forming a first oxide layer above a first portion of the body region, forming a second oxide layer above the high voltage region, forming a first polysilicon layer over the entire substrate region (that will form a selecting gate of the non-volatile device string as well as all the peripheral n-channel device, p-channel device, high voltage devices for both n-channel and p-channel that is not region of the non-volatile device), forming a memory cell region through the etching of the polysilicon layer and oxide, forming a different doping concentration by ion implantation to adjust Vt for the non-volatile device as well as the lower the resistor between the flash cell channel, :forming a spacer, forming a oxide/nitride/oxide layers above the body region, forming a said second polysilicon layer, forming a word line region for the flash gate, :forming a second spacer between the flash word line, forming a oxide/nitride/oxide layers above the body region, forming a said third polysilicon layer or polysilicon and polycide layer over a oxide/nitride/oxide layers above the body region, forming a adjacent self align Flash gate by chemical mechanical polishing (known as CMP) or etch back process, forming selecting gates and all the other transistors by removing the first polysilicon layer and the first oxide layer from regions exposed through photo mask step; forming a LDD ion implantation; forming 3^{rd} spacer to define source and drain implant regions of the device; delivering source and drain implants in the defined source and drain regions of the device; forming the dielectric martial, forming the contact, forming the metal layer. Note that the nitride in the stacked oxide/nitride/oxide becomes the charge storage element in the non-volatile device in one embodiment. However, the low doped polysilicon in a structure having tunnel oxide/low doped polysilicon/dielectric material or materials/Gate known as a floating gate becomes the storage element. The same method in this invention may be applied to a floating gate cell. In order to simplify this invention, only the stacked structure of oxide/nitride/oxide will be illustrated

In some embodiments, the semiconductor substrate is a p-type substrate. In such embodiments, the first well is an n-well formed using a number of implant steps each using a different energy and doping concentration of Phosphorous. Furthermore, in such embodiments, the second well is a p-well formed using a number of implant steps each using a different energy and doping concentration of Boron. In some embodiments, the implant steps used to form the n-well and p-well are carried out using a single masking step.

In some embodiments, the first dielectric layer further includes an oxide layer and a nitride layer and the second dielectric layer is an oxide layer. Moreover, the thickness of the second oxide layer is greater than that of the first oxide layer.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a simplified NAND Flash core architecture with an unit NAND string and a transistor schematic diagram of an unit NAND string, as known in the prior art.

FIG. 2 is a simplified cross section of a single NAND flash cell, as known in the prior art.

FIG. 3a is a simplified cross section of a NAND string, as known in the prior art. FIG. 3b is a simplified view of cell array layout of a NAND string, as known in the prior art.

FIG. 4 is a cross-sectional view of a NAND Flash cell in accordance with one embodiment of the present invention.

FIG. 5 is a cross-sectional view of a single string of NAND flash, in accordance with one embodiment of the present invention.

FIG. 6 is a cross-sectional view of a semiconductor substrate in which an integrated circuit including the non-volatile memory device of FIG. 4 is formed.

FIG. 7 is a cross-sectional view after the formation of the screen oxide.

FIG. 8 is a cross-sectional view after the formation of the nitride deposition over the screen oxide

FIG. 9 is a cross sectional view after formation of the trench isolations.

FIG. 10 is a cross sectional view after formation of the deposition of oxide.

FIG. 11 is a cross sectional view after formation of the CMP.

FIG. 12 is a cross sectional view after formation of the several wells. Note that the process steps of the isolation formation (FIG. 9) and the several types of well formation (FIG. 12) can be exchanged.

FIG. 13 and FIG. 20a are a cross sectional view after the growing the different thickness of the multiple gate oxide and a cross sectional view after the formation of the first polusilicon, polycide (together called as polysilicon) and the 3^{rd} dielectric layer. The cross sectional view of FIG. 16a shows the multiple gate oxide regions.

FIG. 14 is a cross sectional view after the formation of the region of the non-volatile device. FIG. 14 is also a cross sectional view after doping of the region through ion implantation for the adjustment of Vt of the word line as well as reducing the resist value between the adjacent NAND word lines.

FIG. 15 is a cross sectional view after the formation of the first spacer, and deposition of oxide, nitride, oxide, polysilicon layer, and hard mask layer

FIG. 16 is a cross sectional view after the formation of the Flash gate by Reactive ion etching using a photomask step process.

FIG. 17 is a cross sectional view after the formation of the second spacer.

FIG. 18 is a cross sectional view after the deposition of oxide, nitride, oxide, and polysilicon layer.

FIG. 19 is a cross sectional view after the formation of the self-aligned Flash gate by Reactive ion etching or a CMP process without using photo mask step.

FIG. 20 and FIG. 20a are a cross sectional view after the formation of the logic gate for the thin and thick oxide gate by using the photomask process step.

FIG. 21 and FIG. 21a is a cross sectional view after the formation of the ion implantations for LDDs.

FIG. 22 is a cross sectional view after the formation of the third spacer.

FIG. 23 is a cross sectional views after the formation of the source and drain region by using the photo mask for the transistors.

FIG. 24 is a cross sectional view after the formation of the contact region by using the photo mask process.

FIG. 25 shows a cross sectional view after the formation of the first metal layer by using the photo step process.

FIG. 26 is a cross sectional view up to the first metal layer in a NAND flash cell string.

FIG. 27 is a cross-sectional view and its layout to compare a conventional method with a current invention in order to make a NAND cell.

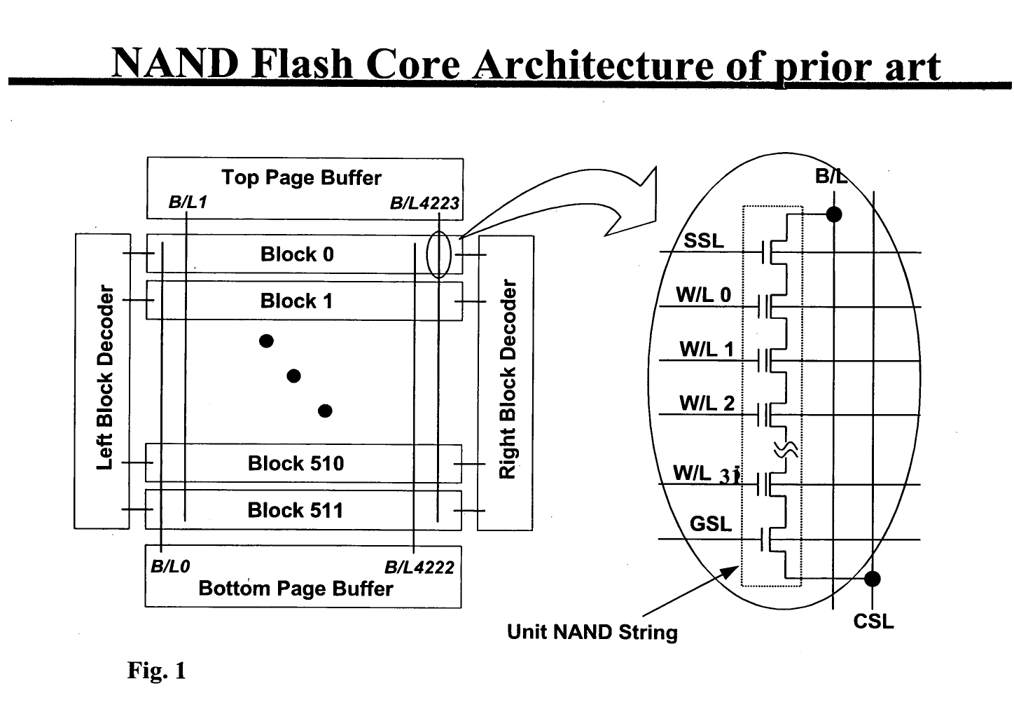

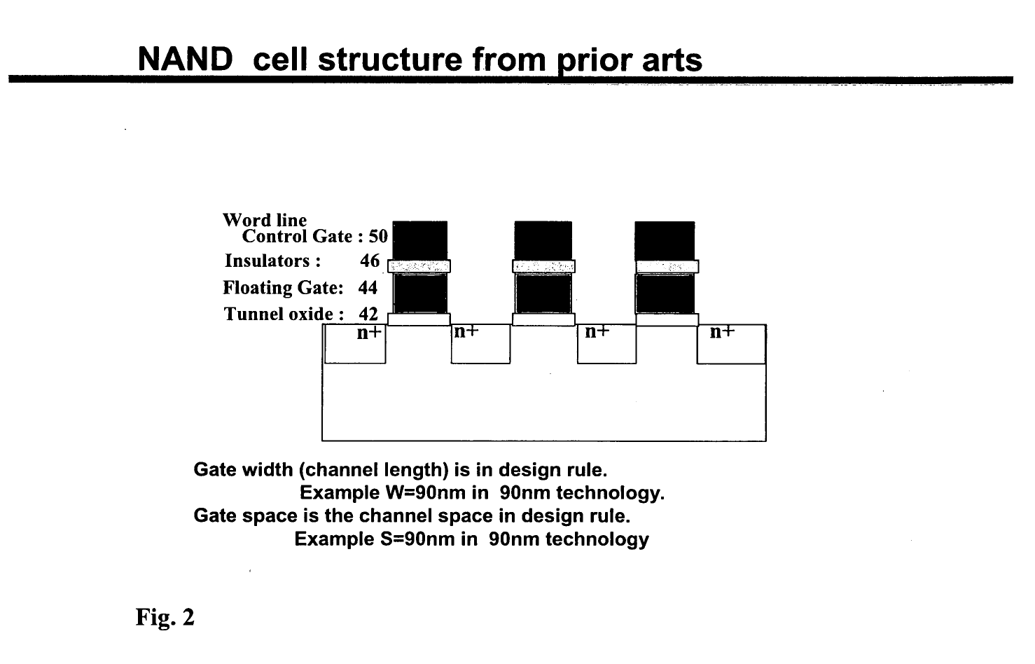

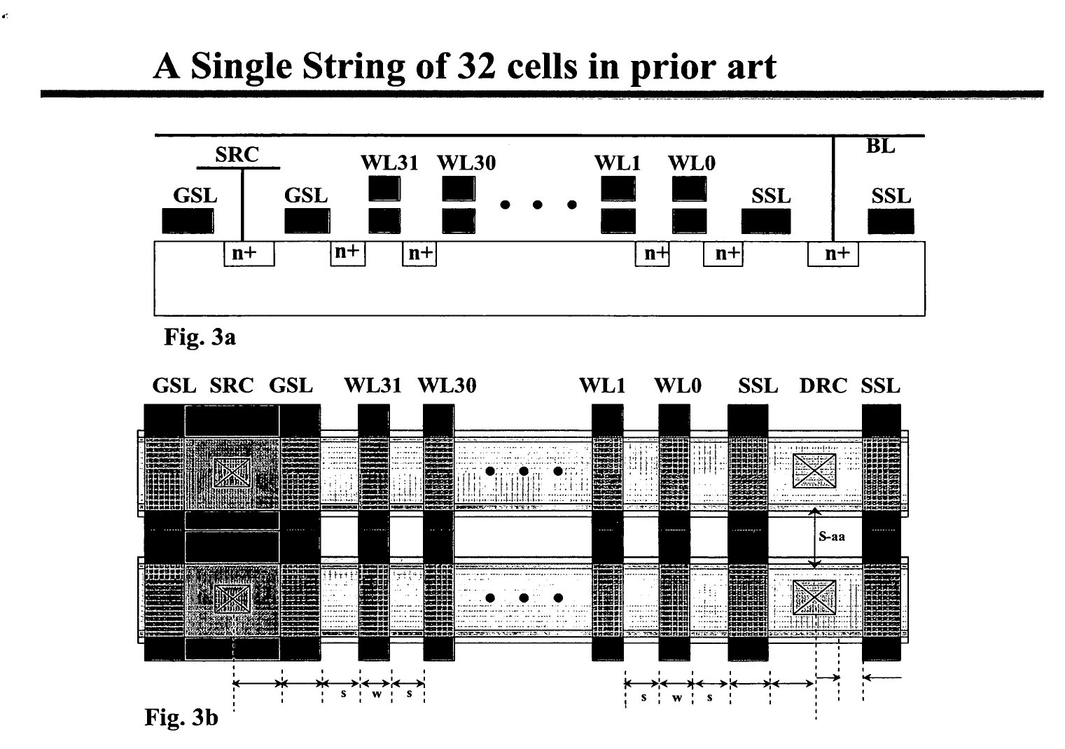

### DETAILED DESCRIPTION OF THE INVENTION

It is very difficult to manufacture to have a pair of devices or a string of NAND cell having a separation of less than 400 A between devices due to the limit of lithography. According to the present invention, a self-aligned method to solve this problem is provided and a method using this invention for forming a non-volatile memory device is provided. According to the present invention, a minimum space between device is not limited by a photo lithography, but by the breakdown of the device operation. Although the invention has been applied to a single integrated circuit device in a memory application, there can be other alternatives, variations, and modifications. For example, the invention can be applied to other device, embedded memory applications, including those with logic or microcircuits, and the like. Also the invention can be applied to the other method of defining the critical line width and or the alignment scheme in manufacturing.

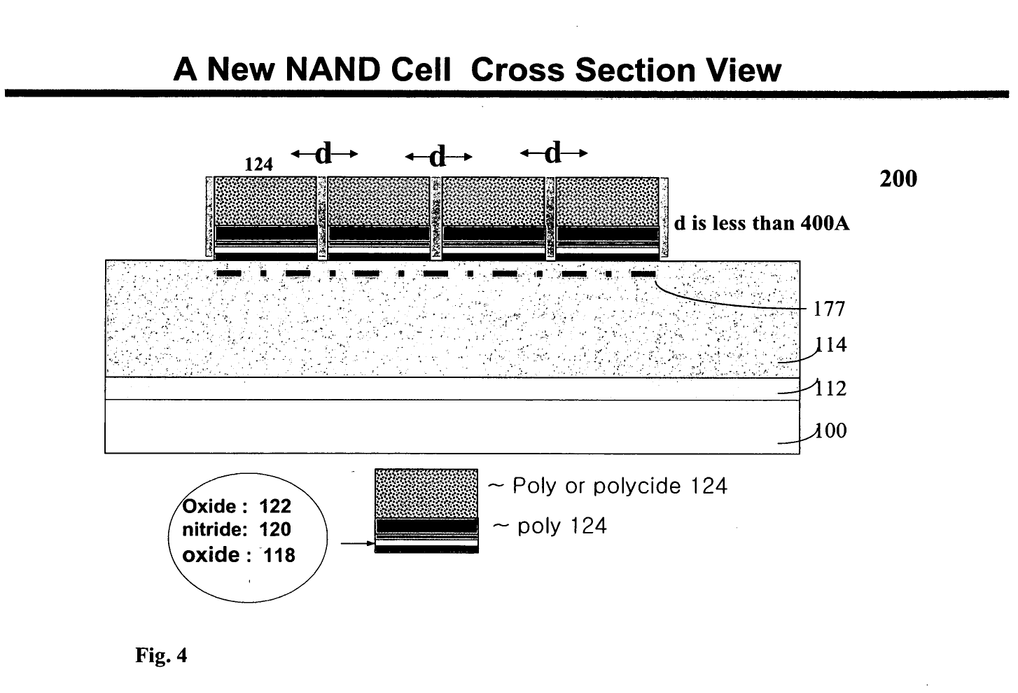

FIG. 4 is a cross-sectional view of some of the regions of non-volatile memory device 200 (hereinafter alternatively referred to as device 200), in accordance with the present invention. Device 200 which is formed in, e.g., a p-type semiconductor substrate or a p-well formed in an n-type semiconductor substrate, includes, in part, a control gate (or called as word line or flash gate) 124, lightly doped regions 177 formed in p-well 114. Control gate 124, which is typically formed from polysilicon or polycide or combination of these, is separated from p-type substrate or p-well layer 114 via oxide layer 118, nitride layer 120 and oxide layer 122. A NAND flash cell is a non-volatile memory device.

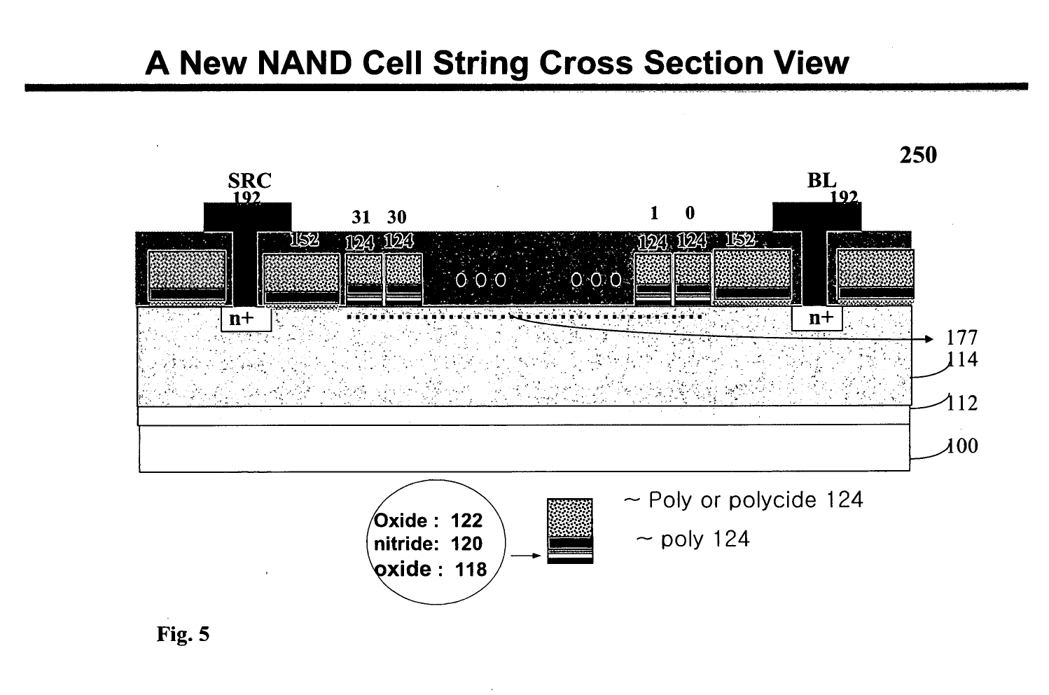

FIG. 5 is a cross-sectional view of a single string of NAND cell array 250 (hereinafter alternatively referred to as device 250), in accordance with the present invention. A single string of NAND cell array of 250 has selecting gates 152's for the source side and the drain side, which is also typically formed from polysilicon, is separated from substrate 100 via layer 136, and a predefined numbers of NAND cell of 200, typically 32 cells or 64 cells. Layer 136 may be an oxide layer or oxinitride layer or any other dielectric layer. Selecting gate 152 is separated from the control gate 124 from via insulators. Each word line of a single string of NAND cells of structure 250 is separated by the self-aligned spacer of 132, and is connected through low doping ion implantation to the channel region. Since the separation between the devices is less than 400 A, there will be a negligible effect of the source and drain resistance between the adjacent device. Note that the spacer region is the source and drain region of NAND device. A sequence of steps adapted to manufacture device 200 and 250 is described below. In the following, it is understood that similar elements or regions in the drawings are identified with similar reference numerals. Moreover, after various regions or elements in a drawing are identified with their respective reference numerals, the subsequent drawings may omit those reference numerals for simplification purposes.

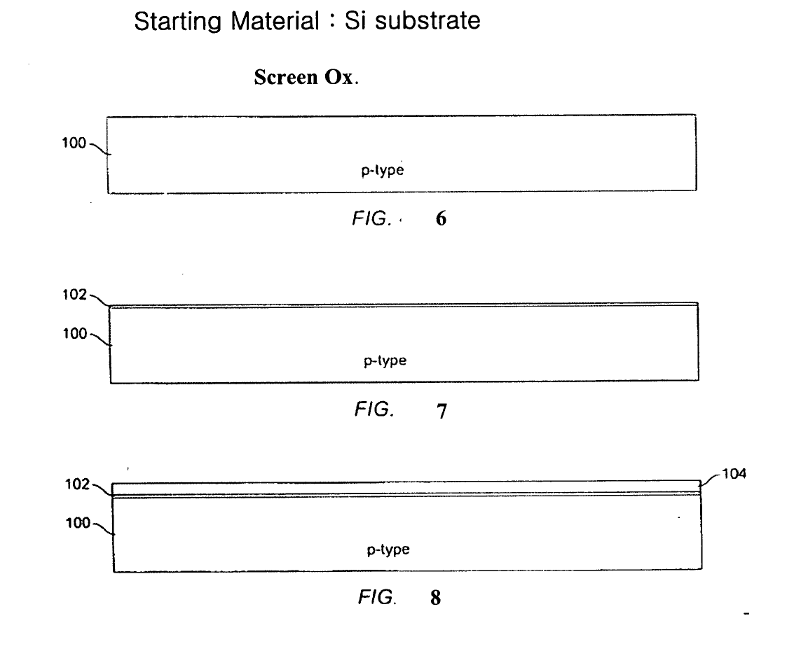

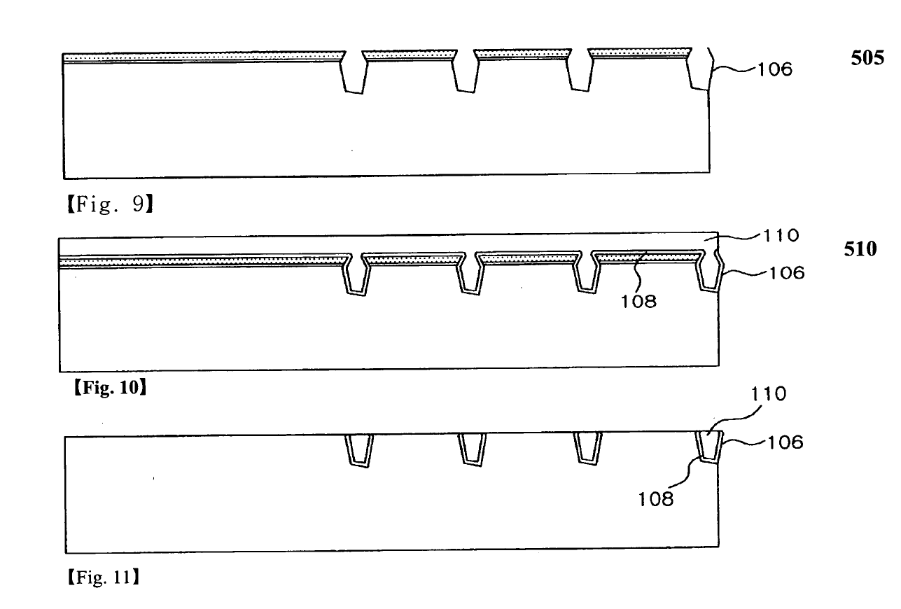

FIG. 6 shows a semiconductor substrate 100 in which the non-volatile device 200 and a string of memory cell 250 shown in FIG. 4 is formed. In the exemplary embodiment described above, substrate 100 is a p-type substrate. It is understood that in other embodiments, substrate 100 may be an n-type substrate. To form non-volatile device 200, a layer of screen oxide 102 having a thickness in the range of, e.g., 60-1000 A, is grown on substrate 100 using conventional thermal oxidation processes, as shown in FIG. 7. Next, as shown in FIG. 8, a layer of silicon-nitride 104 having a thickness in the range of, e.g., 500-1500 A, is deposited on pad oxide layer 102. It is understood that the various layers and thicknesses shown in the FIG. 7 are not drawn to scale. Next, using conventional masking and etching steps, shallow trenches 106 are formed in substrate 100, thereby forming structure 505 as shown in FIGS. 9 and 10. It is understood that in some embodiments, isolation regions formed using conventional locos isolation (not shown) techniques may be used in place of trenches 106.

After shallow trenches 106 are formed, a layer of oxide having a thickness of, e.g., 150 Å, is grown over structure 104 not shown in this Fig. This oxide is also grown in trenches 106. Next, a layer of TEOS having a thickness of, e.g., 5000-10,000 Å is deposited on the oxide. This TEOS layer is also deposited in trenches 106. Thereafter, using a planarization technique, such as chemical-mechanical polishing (CMP), the resulting structure is planarized. FIG. 10 shows the resulting structure 510 after the planarization process. As is seen from FIG. 11, as all the layers overlaying substrate 100, except for the oxide layer 108 and TEOS layer 110 formed in trenches 106, are removed.

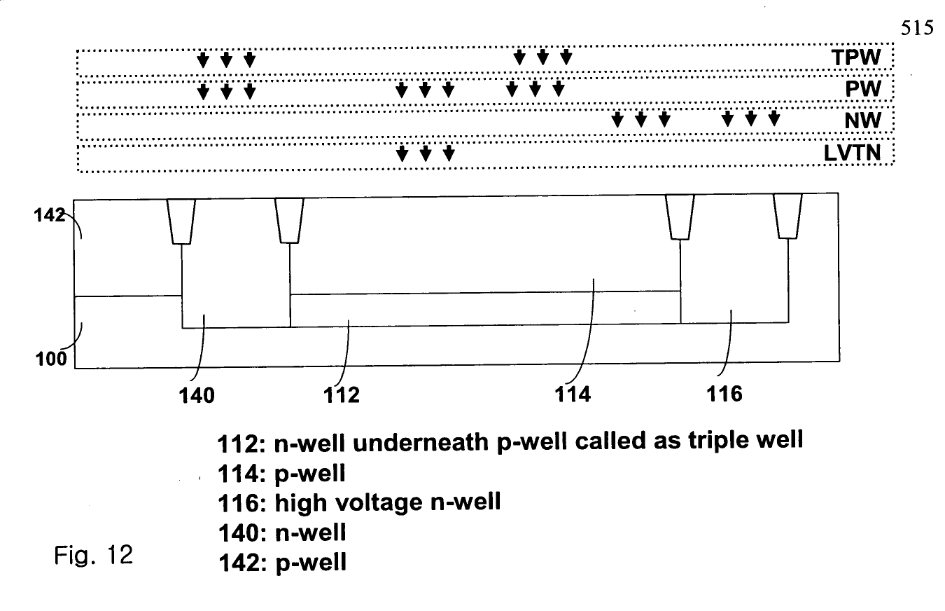

Next, as shown in FIG. 12, using conventional photo-resist patterning and etching steps, n-well 112 and p-well 114 are formed. As seen from FIG. 12, n-well 112 is deeper than and formed before p-well 114. Note that this n-well 112 and p-well 114 can be used as the same mask step. In some embodiments, a Phosphorous implant with a concentration of 2.0 e¹³ atoms/cm² and using an energy of 1.5 Mega-electron volts is used to form n-well 112. In such embodiments, three to six separate Boron implants are used to form p-well implant 114. The first Boron implant is made using a concentration of 2.0 e¹³ atoms/cm² and an energy of 600 Kilo-electron volts. The second Boron implant is made using a concentration of 1.0 e¹³ atoms/cm² and an energy of 300 Kilo-electron volts. The third Boron implant is made using a concentration of 4.0 e¹³ atoms/cm² and an energy of 160 Kilo-electron volts. The fourth Boron implant is made using a concentration of 6.0 e¹³ atoms/cm² and an energy of 70 Kilo-electron volts. The fifth Boron implant is made using a concentration of 1.0 e¹³ atoms/cm² and an energy of 300 Kilo-electron volts. The above phosphorous and Boron implants are performed using the same masking step.

Because, the Phosphorous implant is performed using a relatively high energy, relatively few Phosphorous impurities may remain in p-well 114. Therefore, in accordance with the present invention, advantageously very few Boron impurities in p-well 114 are neutralized (i.e., compensated) by the phosphorous impurities. After the above implants, a thermal anneal is performed at the temperature of, e.g., 950-1050° C. for a period of, e.g., 30 seconds. The resulting structure is shown in FIG. 12.

Next, using conventional masking and ion implantation steps, highly doped p-well region of 142 is formed (see FIG. 12). In some embodiments, three to five separate Boron implants are used to form p-well implant 140. If four Boron implants are used, the first Boron implant is made using a concentration of, e.g., 1-3.3 e¹² atoms/cm² and an energy of 20 Kilo-electron volts (Kev). The second Boron implant is made using a concentration of, e.g., 5-6.5 e¹² atoms/cm² and an energy of 70 Kev. The third Boron implant is made using a concentration of, e.g., 2.5-3.4 e¹² atoms/cm² and an energy of 180 Kev. The fourth Boron implant is made using a concentration of, e.g., 2-3.5 e¹³ atoms/cm² and an energy of 500 Kilo-electron volts.

Next using conventional masking and ion implantation steps, highly doped n-well region 140 is formed (see FIG. 12). In some embodiments, three to five separate Phosphorous implants are used to form n-well implant 24. If four Phosphorous implants are used, the first Phosphorous implant is made using a concentration of, e.g., 5.7 e¹² atoms/cm² and an energy of 50 Kev. The second Phosphorous implant is made using a concentration of, e.g., 6.6 e¹² atoms/cm² and an energy of 150 Kev. The third Phosphorous implant is made using a concentration of, e.g., 5.0 e¹² atoms/cm² and an energy of 340 Kev. The fourth Phosphorous implant is made using a concentration of, e.g., 4.0 e¹³ atoms/cm² and an energy of 825 Kilo-electron volts. In some embodiments, a Phosphorous implant with a concentration of 2.0 e¹³ atoms/cm² and using an energy of 1.5 Mega-electron volts is used to form n-well 116. After the above implants, a thermal anneal is performed at the temperature of, e.g., 1000° C. for a period of, e.g., 10 seconds. Next, as shown also in FIG. 12, a second n-well 140 is formed adjacent n-well 112 and p-well 114. N-well 116 that extends to the surface of substrate 100 has a depth that is substantially the same as the combined depth of n-well 112 and p-well 114. The second p-well is 142. The resulting structure 515 is shown in FIG. 12. Note that the process sequence steps of FIG. 8˜8a and FIG. 12 can be exchanged; all the wells can be formed before the formation of the isolation and the formation of isolation steps can be formed after the formation of all the wells.

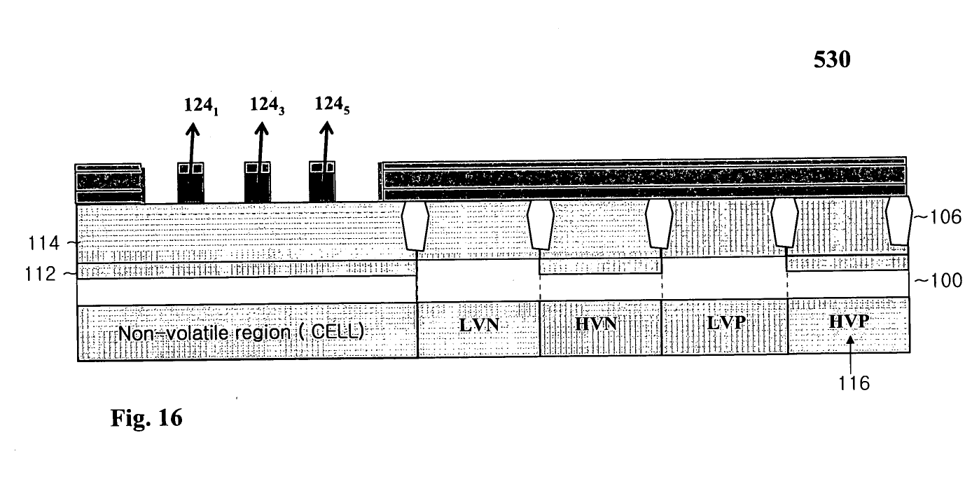

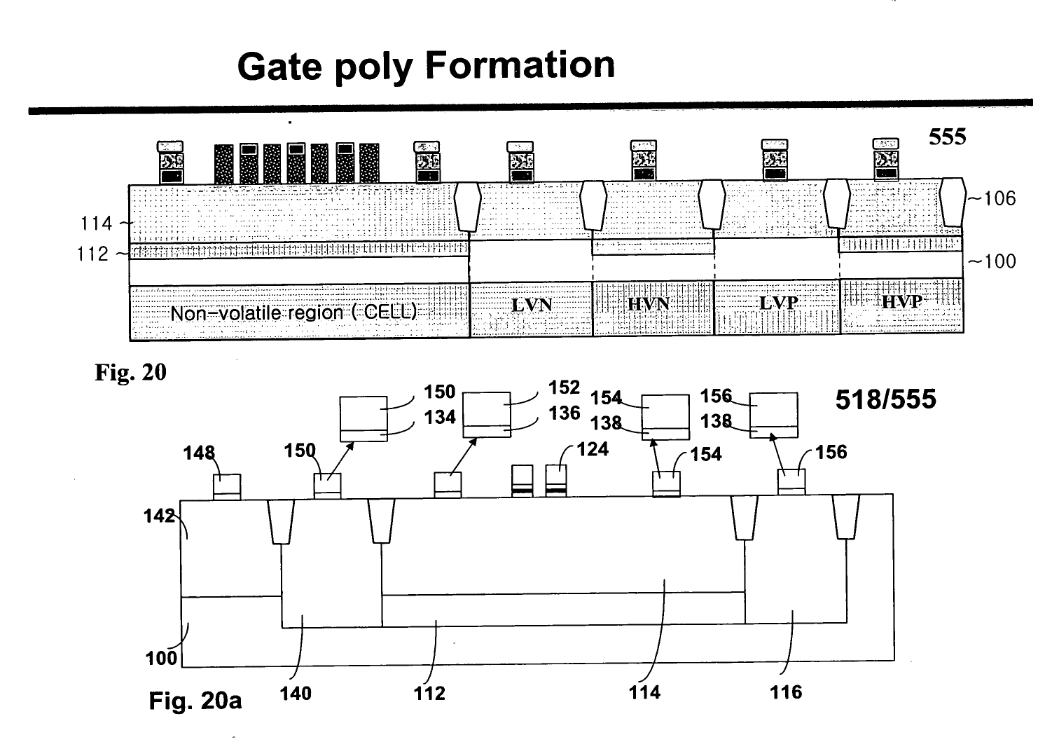

Next, using several masking steps, three ( or two) layers of oxide thickness each having a different thickness are thermally grown. In the surface regions identified with reference numeral 134 shown in FIG. 20a, the oxide layer has a thickness in the range of, e.g., 15-100 Å. The semiconductor substrate underlying oxide layer 134 is used to form core transistors having relatively high speed. In the region identified by reference numeral 136, the oxide layer has a thickness in the range of, e.g., 40-100 Å. The semiconductor substrate underlying oxide layer 136 and overlaying p-well 114 is used to form devices adapted to operate with voltages substantially similar to the Vcc voltage (i.e., 3.3 volts) and the selecting gate, such as input/output transistors. In the region identified by reference numeral 138, the oxide layer has a thickness in the range of, e.g., 100-450 Å. The semiconductor substrate underlying oxide layer 138 is used to form high-voltage transistors, such as high-voltage charge pump devices. The process of making multiple, e.g. 3, layers of oxide each with a different thickness is known to those skilled in the art and is not described herein. In some other embodiments, oxide layers 136 and 138 have the same thickness in the range of, e.g., 90-250 Å. In some other embodiments, oxide layers 134 and 136 have the same thickness in the range of, e.g., 40-100 Å. Structure 518 of FIG. 16b shows the result of performing these steps on structure, in accordance with the present invention. It is understood that the drawings do not show some of the intermediate steps involved in forming structure 518

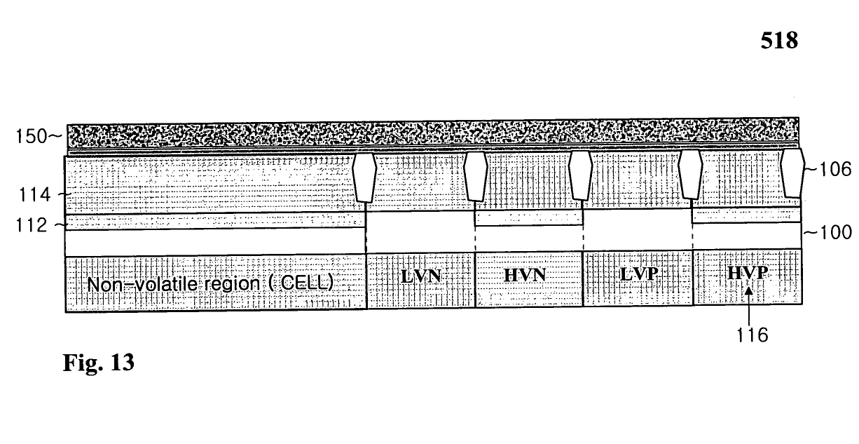

Next, as shown in FIG. 13, a layer of polysilicon and or polycide (note that the polycide can be formed through the subsequent salicide process step also) 150 having a thickness in the range of, e.g., 300-3200 Å, is deposited. Thereafter, a layer of nitride or oxide or hard mask 145 having a thickness in the range of, e.g., 300-1500 Å.

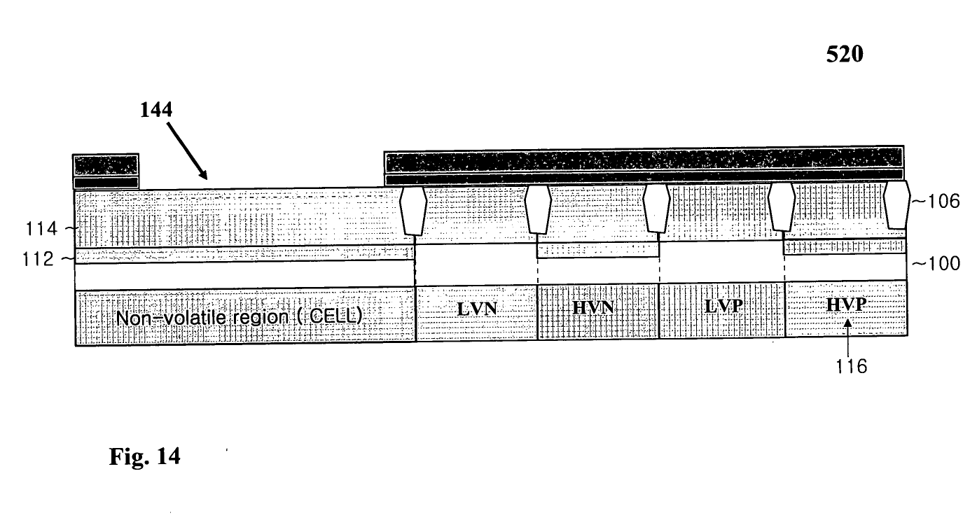

Next, using standard photo-resist masking and patterning techniques, photo-resists masks having 144 are formed over polysilicon layer 150. Thereafter, using conventional reactive ion etching (RIE) steps, hard mask layer or oxide layer 145 and polysilicon layer 150 are removed from all regions positioned below masks 144 to form the region of 144. Thereafter ion implantation is formed to adjust the doping level in the control gate. The amount of dose and energy as well as ion implant material will be adjusted to have a Vt of −2.0 to 0.5V. Structure 520 of FIG. 14 shows the result of performing these steps. This etched area is the region of the forming the control gate of the non-volatile device structure 200 and 250.

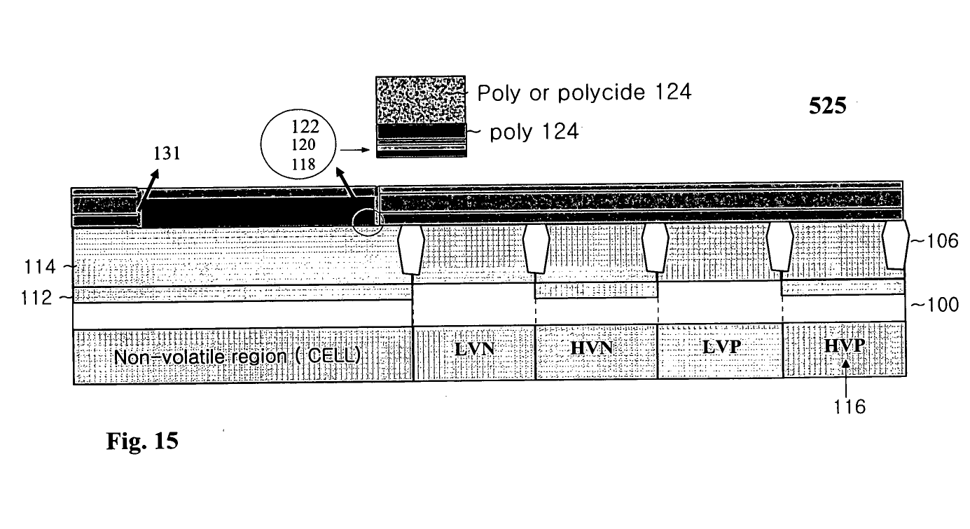

Next, as shown in FIG. 15, a layer of dielectric material (4^{th} dielectric material) having a thickness in the range of, e.g., 300-1500 Å is deposited over structure 520 to form the first spacer 131. Next, as shown in FIG. 15, a layer of thermal oxide 118 having a thickness in the range of, e.g., 15-45 Å, is grown over structure 520. Thereafter, a layer of nitride 120 having a thickness in the range of, e.g., 40-120 Å, is formed over oxide layer 118. Next, a layer of CVD oxide 122 having a thickness in the range of, e.g., 40-70 Å, is deposited over nitride layer 120. Thereafter, during a densification step, the resulting structure is heated to a temperature of, e.g., 700-850° C. for a period of, e.g., 0.1 to 1 hour. After the densification step, a layer of polysilicon (alternatively referred to herein below as poly) 124 having a thickness in the range of, e.g., 500-3000 Å is deposited over CVD oxide layer 122. Poly layer 124 may be doped in-situ or using other conventional doping techniques, such as ion implantation. Note that Poly layer means that poly plus either polycide or salicide or poly itself. FIG. 15 is a cross sectional view after the formation of the first spacer, the deposition of oxide, nitride, oxide, polysilicon layer, and then hard mask layer.

Next using conventional masking steps, a layer of hard mask layer (the dielectric material 145), polysilicon layer 124, oxide 122, nitride 120, and oxide 118 are removed from all regions except those positioned below mask. Structure 530 of FIG. 16 shows the result of performing these steps. This remaining area 124ᵢ is the region of the forming the first portions of the control gates of the non-volatile device structure 200 and 250, where i is an odd number that represents the sequence of the control gates, e.g. 124₁, 124₃, 124₅, etc.

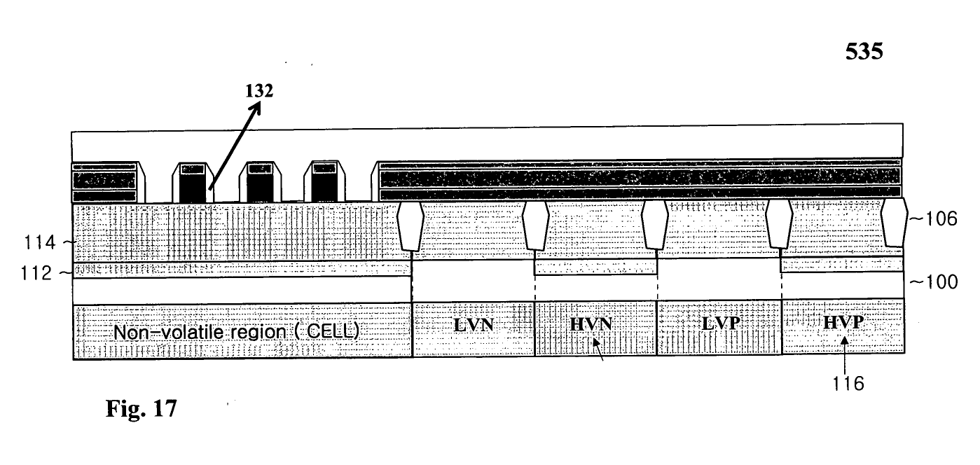

Next, as shown in FIG. 17, a layer of dielectric material having a thickness in the range of, e.g., 100-700 Å depending on the desired spacer width is deposited over structure 530. Next, without using a photo masking step, a reactive ion etching is performed to form the second spacer 132 as shown in FIG. 17. The width of this spacer determined the space (distance) between NAND cells. Note that the spacer width is controlled by the dielectric thickness deposited.

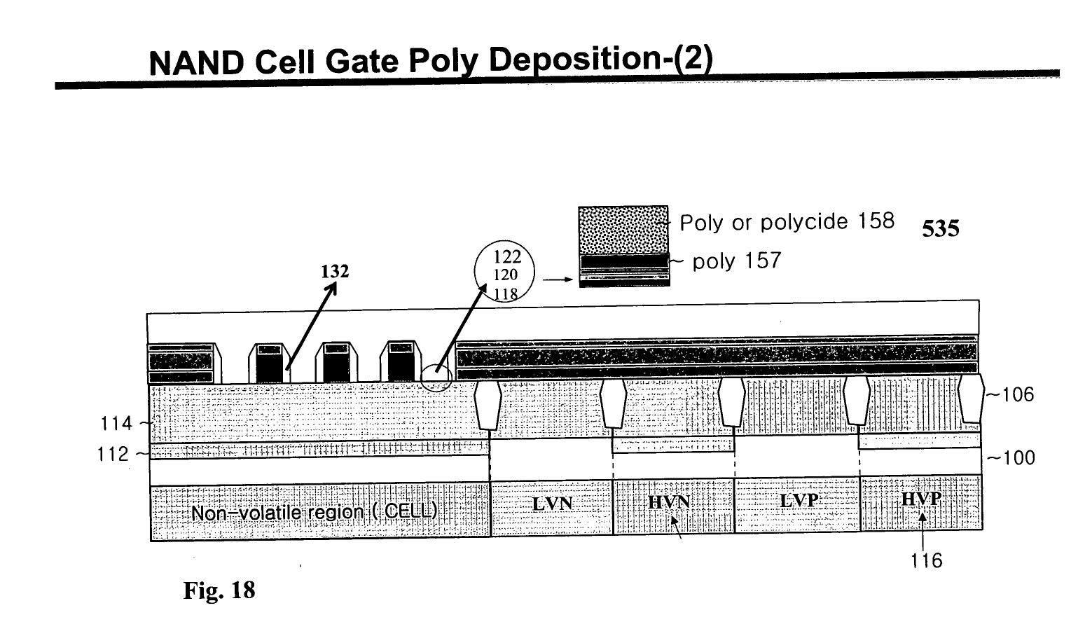

Next, as shown in FIG. 18, a layer of thermal oxide 118 having a thickness in the range of, e.g., 15-45 Å, is grown over structure 535. The oxide 118 is grown on the silicon surface 114 of the body 100. Thereafter, a layer of nitride 120 having a thickness in the range of, e.g., 40-120 Å, is formed over oxide layer 118. Next, a layer of CVD oxide 122 having a thickness in the range of, e.g., 40-70 Å, is deposited over nitride layer 120. Thereafter, during a densification step, the resulting structure is heated to a temperature of, e.g., 700-850° C. for a period of, e.g., 0.1 to 1 hour. After the densification step, a layer of polysilicon (alternatively referred to herein below as poly) 124 having a thickness in the range of, e.g., 500-5000 Å is deposited over CVD oxide layer 122. Poly layer 124 may be doped in-situ or using other conventional doping techniques, such as ion implantation. Note that Poly layer means that poly plus either polycide or salicide or poly itself Also note that the name convention 124 is used as the same as the previous poly layer 124 for the convenience even though it is in the different step process. FIG. 18 shows structure 535 that is formed after the above growth and deposition steps are performed on structure 535. FIG. 18 is a cross sectional view after the deposition of oxide, nitride, oxide, and then polysilicon layer.

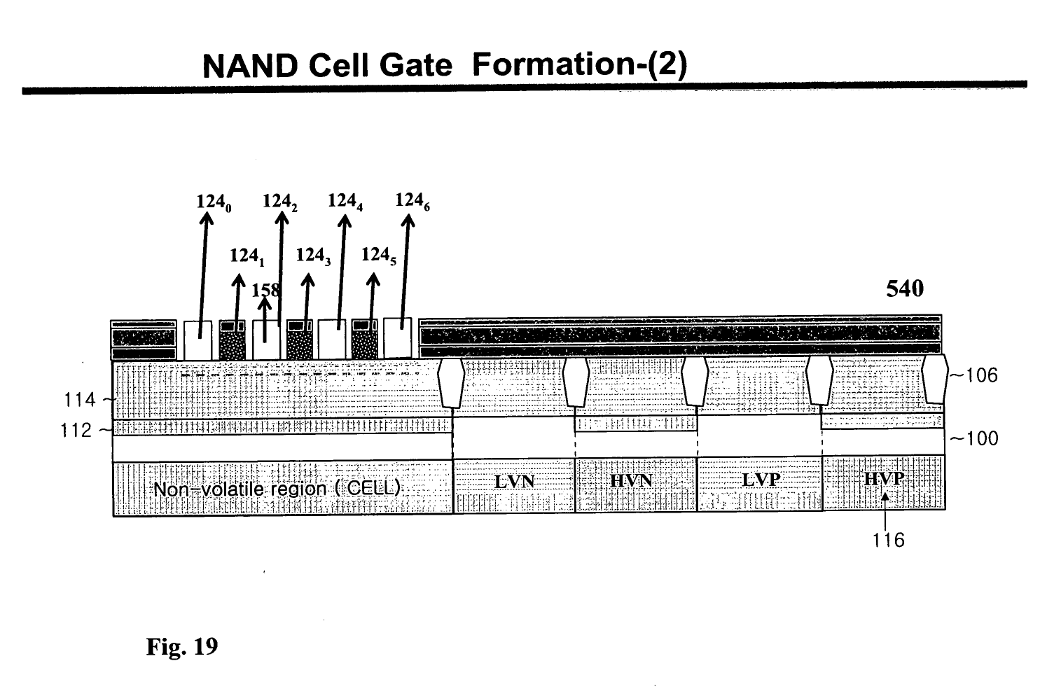

Next, without using a photo masking step, an reactive ion etching of the polysilicon called as an etch back or CMP process is performed to form the self-aligned NAND flash gate. After this CMP step, the complete string NAND cells is formed to form the control gates ( flash gates) 124ᵢ of the structure 535, where i is the sequence of the control gates, e.g. 124₀, 124₁, 124₂, 124₃, etc. Note that the drawn dimension of the word line space for the single string minus two times spacer 132 width becomes the self-aligned word line width. Note that the space (separation) between word line is formed by the spacer 132 which is controllable less than 400 A depending on the spacer thickness. FIG. 19 is a cross sectional view after the completion of forming the control gate 124.

Next, using conventional photo mask steps, the dielectric material 145, polysilicon layer 150 and oxide layers 134, 136, and 138 are removed from all regions except those positioned below mask—to form the gates of the selecting gate 152, the low voltage n-channel and p-channel transistors, and the high voltage n-channel and p-channel transistors such as 148 and 156, shown in FIG. 16 and FIG. 16a. The adjacent n-channel transistors of the flash gates 124 are the selecting gate transistors 152 and 156 for the non volatile device. Structure 555 of FIG. 16 and FIG. 16a shows the result of performing these steps. Poly gate 148 is shown as overlaying gate oxide layer 134 formed above p-well 142. Poly gate 150 is shown as overlaying gate oxide layer 134 formed above n-well 140. Poly gate 154 is not shown (in Fig.) as overlaying gate oxide layer 138 formed above p-well 114. Poly gate 156 is shown as overlaying gate oxide layer 138 formed above n-well 116. Poly gates 148 and 150 respectively form the gates of low-voltage high-speed PMOS and NMOS transistors. Poly gates 154 and 156 respectively form the gates of high-voltage NMOS and PMOS transistors. Poly gate 152 forms the selecting gates of a pair of non-volatile devices and each is shown as overlaying gate oxide layer 136 formed below it.

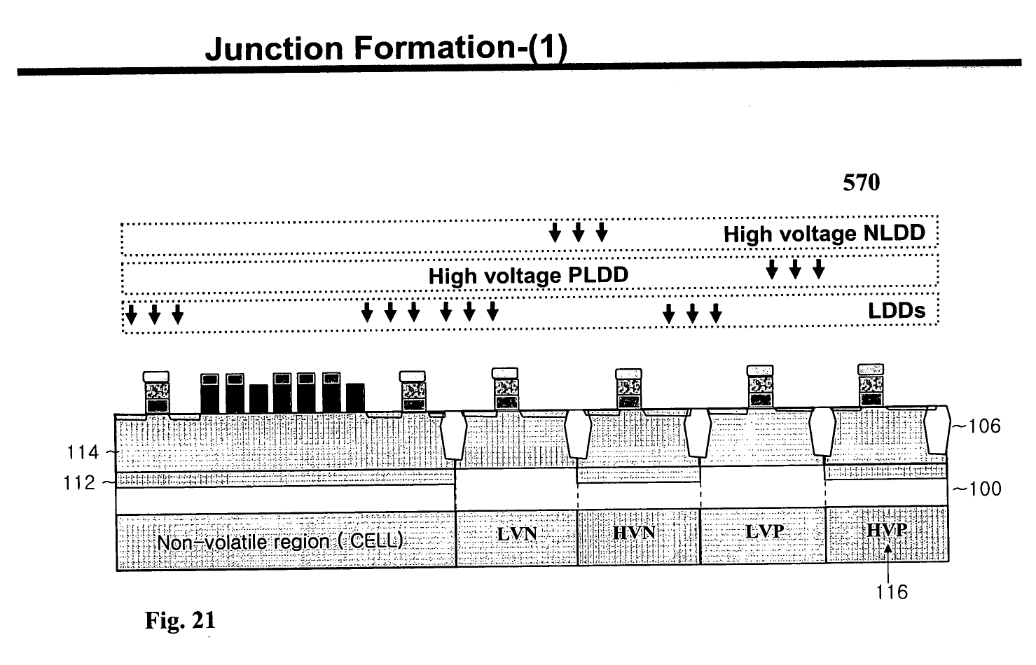

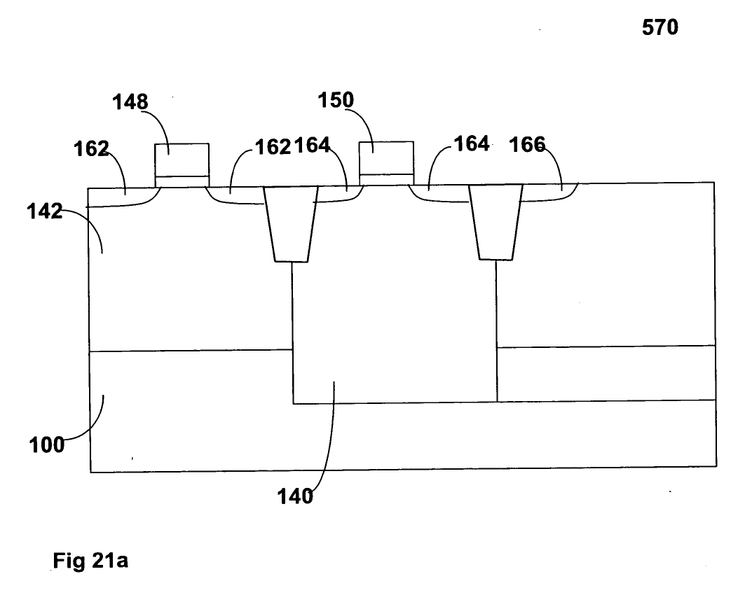

Next, using several masking steps, low voltage n-type lightly doped (LDD) regions 162, low-voltage p-type LDD regions 164, intermediate voltage n-type LDD regions 166, high voltage n-type LDD region 168, and high voltage p-type LDD region 170 are formed. The resulting structure 570 is shown in FIG. 21 and FIG. 21a.

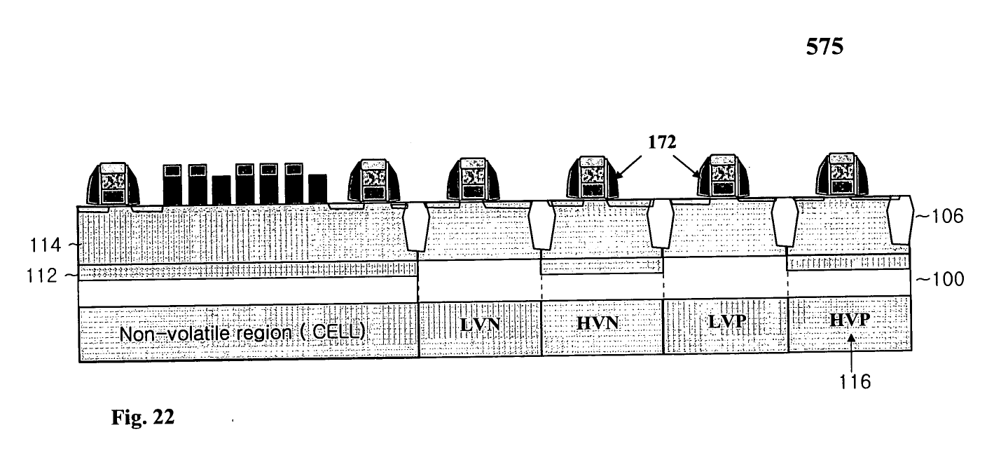

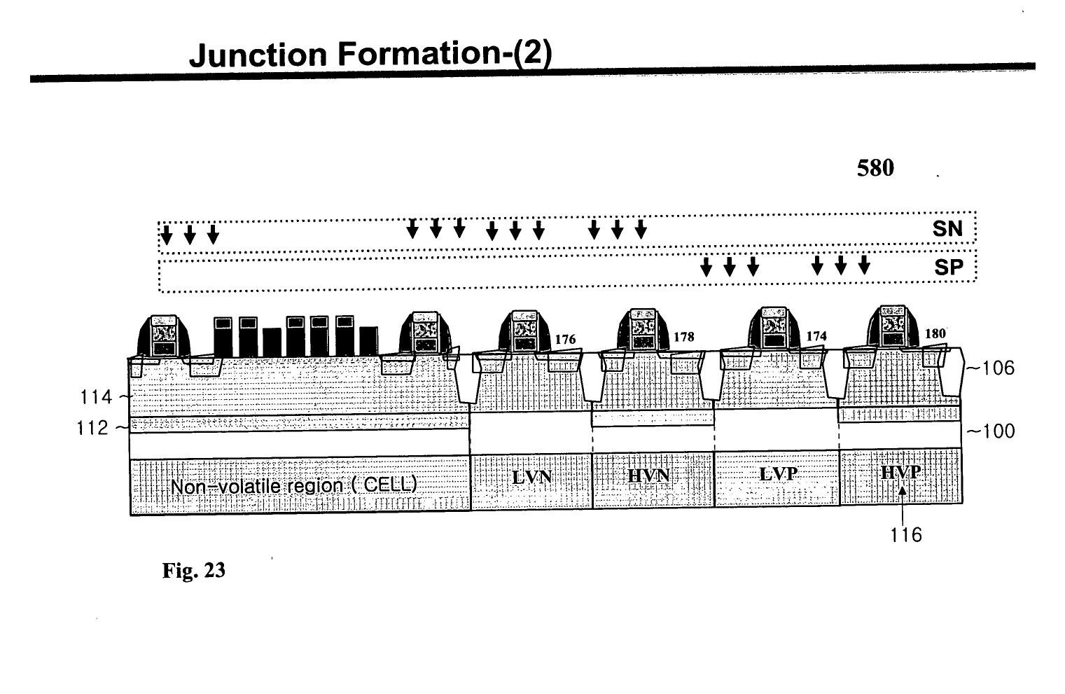

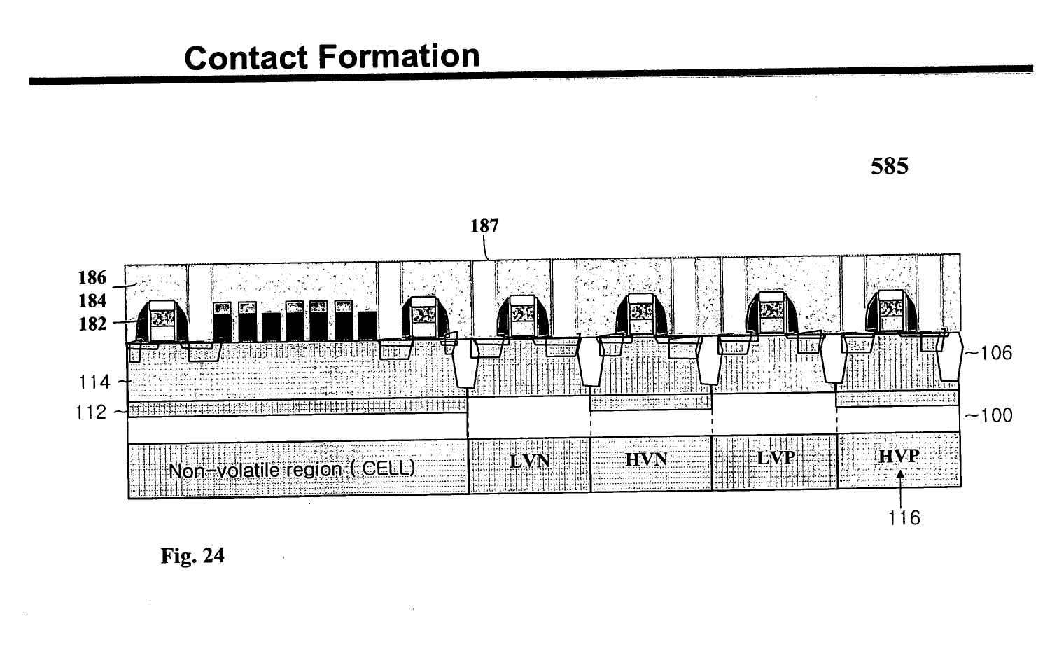

Next, as shown in FIG. 22, using conventional processing steps, side-wall spacers 172 are formed. In some embodiments, each side-wall spacer 172 is made from oxide and each has a thickness in the rage of, e.g., 100-1500 Å. Thereafter, several p⁺ and n⁺ masking steps are performed to form p⁺ source/drain regions 174, n⁺ source/drain regions 176, n⁺ source/drain regions 178, and p⁺ source/drain regions 180. In some embodiments, the doping concentration of Boron used to form p⁺ source/drain regions 174 is the same as that used to form p⁺ source/drain regions 180. In some other embodiments, the doping concentration of Boron used to form p⁺ source/drain regions 174 is different from that used to form p⁺ source/drain regions 180. In some embodiments, the doping concentration of Arsenic used to form n⁺ source/drain regions 176 is the same as that used to form n⁺ source/drain regions 178. In some other embodiments, the doping concentration of Arsenic used to form n⁺ source/drain regions 176 is different from that used to form n⁺ source/drain regions 178. The resulting structure 580 is shown in FIG. 23.

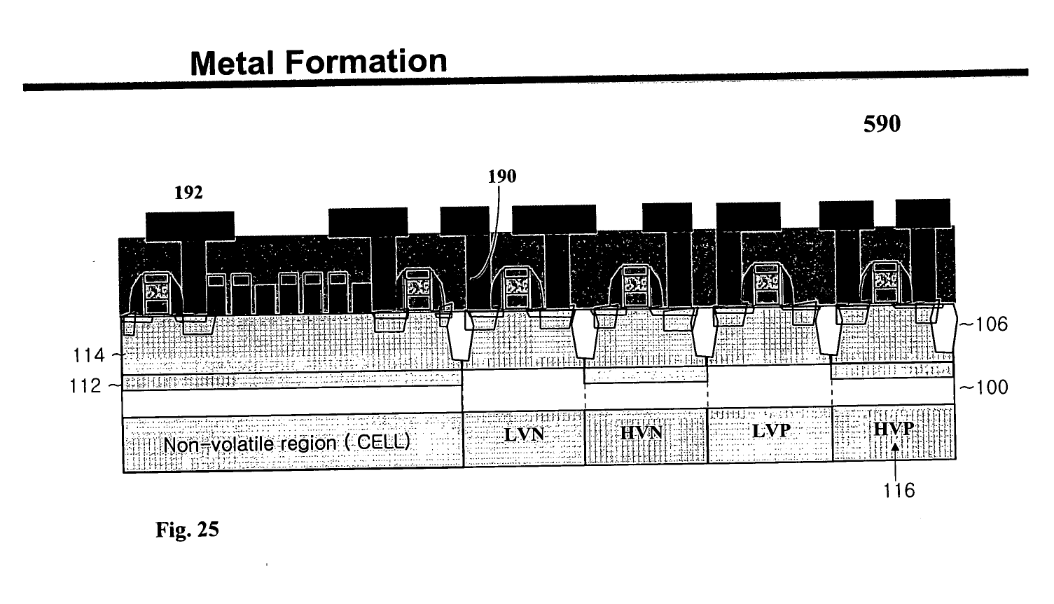

Next, polycide or refractory metal is deposited over structure 580. Thereafter, a high-temperature anneal cycle is carried out. As is known to those skilled in the art, during the anneal cycle, refractory metal reacts with silicon and polysilicon, but not with silicon-nitride or silicon-oxide. In the resulting structure is not shown in Fig., Salicided layers are identified with reference numeral 182. Depending on the technology, this salicide step can be omitted. Next, a layer of nitride 184 is deposited over structure 580 and a layer of oxide 186 is deposited over nitride layer 184. Note that either layer 186 or 186 can be omitted. Next, contact 187 are formed in nitride layer 184 and oxide layer 186 to expose the under laying Salicide layers. Thereafter, a barrier metal, such as Titanium-nitride 188 is sputter-deposited partly filling the contacts. Next, Tungsten 190 is deposited over Titanium-nitride layer to fills the remainder of the contacts. The deposited Tungsten is commonly referred to as Tungsten Plug. Next, using a CMP technique, the Tungsten deposited structure is planarized. Next, a metal such as Aluminum or Copper is deposited and patterned over the planarized structure. The resulting structure 590 is shown in FIG. 25. As is seen from FIG. 25, each contact has disposed therein a Titanium-Nitride layer 188 and Tungsten layer 190. The deposited and patterned Al or Copper layers are identified with reference numeral 192.

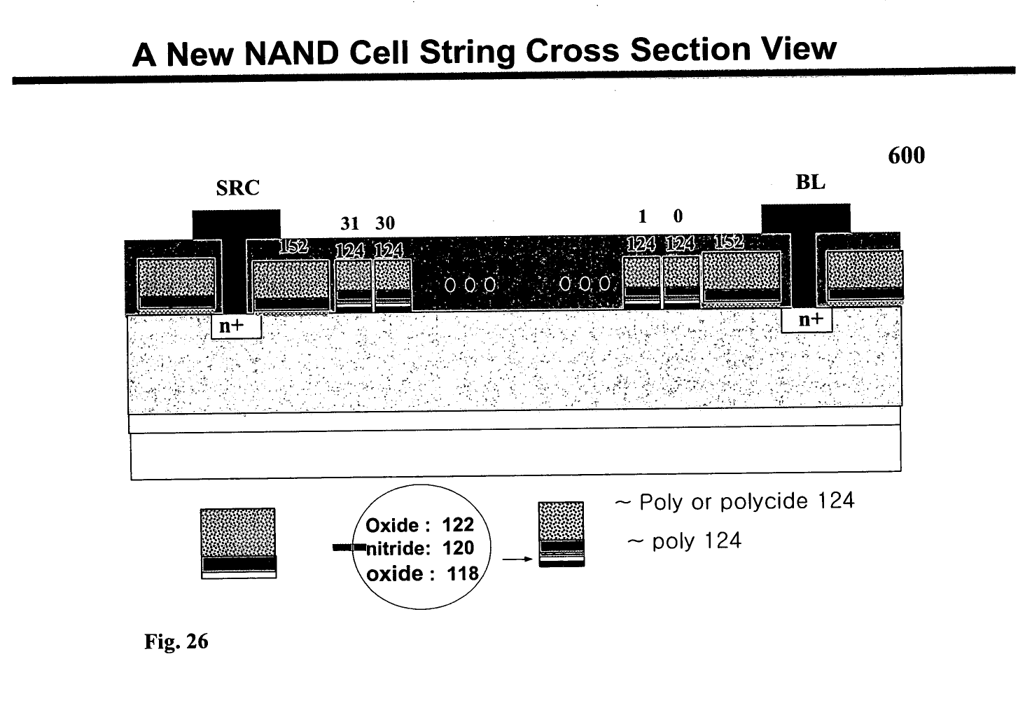

FIG. 26 shows the cross sectional view of the structure of 600 which has the process step up to the first metal1 for a single string NAND cells.

The description above is made with reference to a single metal layer. However, it is understood that additional metal layers may be formed over metal layers 192 in accordance with known multi-layer metal processing techniques.

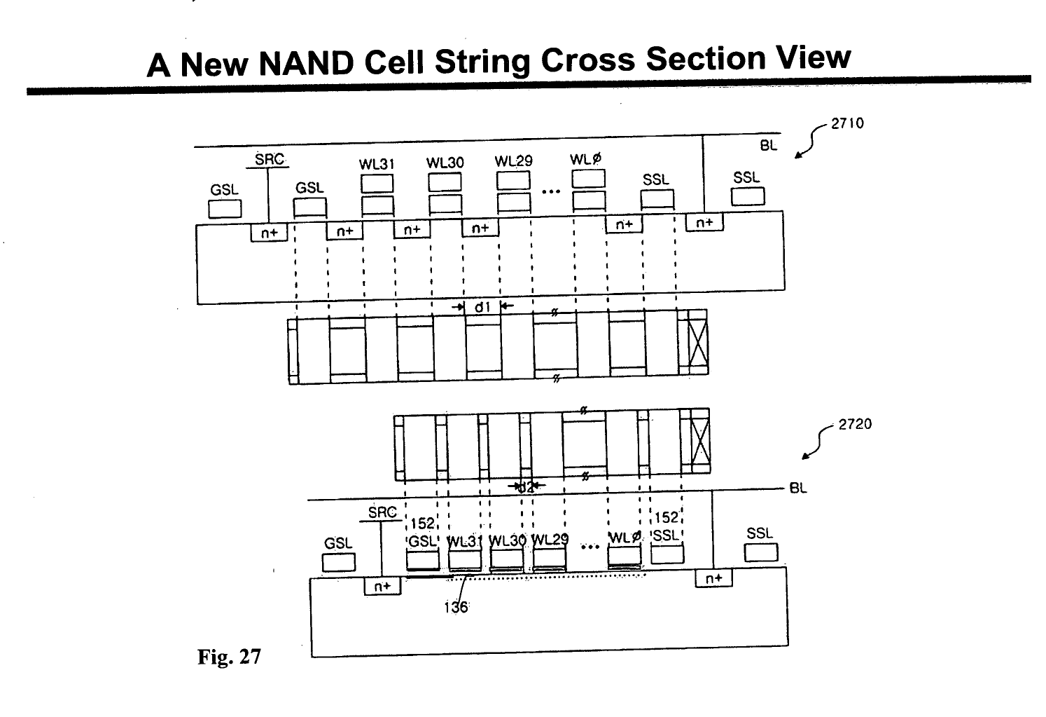

FIG. 27 shows the cross sectional view of the structure of 600 which has the process step up to the first metal1 for a single string NAND cells and the related layout for a comparison for a conventional method and this invention.

It is shown in FIG. 27 that the cell size of this current invention by using a self aligned control gate is about half size of a conventional cell size. This reduction of a cell size is achieved through making a smaller space between control gates by utilizing a self-aligned spacer and without using the heavily doped source drain junction area. The lightly doped junctions underneath the spacer in the memory cell array act as a source and drain because the width of the spacer, becomes a region of the source and drain, is very small. The space between the control gates is determined by the spacer thickness and can be achieved below 300 A.

Programming, Reading, and Erasing

The operation of this NAND cell is as followings. Programming of NAND Flash is done by applying a high programming voltage, e.g. 12V to 20V, to the control gate of the memory cell to be programmed; either 0V or an intermediate voltage, e.g. 6V-10V, to the control gates of all the memory cell other than the memory cell to be programmed; an intermediate voltage, e.g. 6V-10V, to the gate of the select transistor for drain (SSL); either 0V or an intermediate voltage, e.g. 5V-8V, to the bit line; 0V to the gate of the select transistor for source (GSL); 0V to the source line (SRC), and 0V to the bulk.

Reading of the NAND Flash is done by first pre-charging the bit line node to VCC, and then next applying 0V to the source line, VCC to the gate of the select transistor for drain (SSL), VCC to the gate of the select transistor for source (GSL), Vcc to the control gates of the non-selected memory cells, a reading voltage, e.g. 0V, to the control gate of the selected memory cell, and 0V to the bulk.

Erasing of the NAND Flash can be done by applying 0V to the gate of the select transistor for drain (SSL), 0V to the gate of the select transistor for source (SSL), and a high voltage, e.g. 13V-20V, to the source line, the bit line, and the bulk terminals.

Erasing of the NAND Flash can also be done by applying a high negative voltage, e.g. −16V to −20V, to the control gates, 0V to the source line, 0V to the bit line, 0V to the bulk, 0V to the gate of the select transistor for drain (SSL), and 0V to the gate of the select transistor for source (GSL).

| | | | Erase | Erase |
|---|---|---|---|---|
| Voltage | Program | Read | method 1 | method 2 |
| BL | either 5 V-8 V | VCC | 13-20 V | 0 V |
| | or 0 V | | | |
| SSL | 6 V-10 V | VCC | 0 V | 0 V |
| Control gate of the | either 0 V or | VCC | 0 V | −16 V |
| non-selected cell | 6 V-10 V | | | to −20 V |
| Control gate of the | 12 V-20 V | 0 V | 0 V | −16 V |
| selected cell | | | | to −20 V |
| GSL | 0 V | VCC | 0 V | 0 V |
| Source line SRC | 0 V | 0 V | 13-20 V | 0 V |
| Bulk (well) | 0 V | 0 V | 13-20 V | 0 V |

In conventional NAND-type Flash, the regions in the channel between adjacent floating gates, of length ‘d’ as shown in FIG. 4, are highly doped with n+ type material to form the source and drain regions. However, in the present invention, this region is lightly doped and forms virtual source and drain regions through the applied voltages of adjacent control gates. Furthermore, the distance ‘d’ is relatively short compared to conventional NAND-type Flash, e.g. 300 Angstroms, and thus the region will be within depletion range, which allows current to flow with low resistivity.

What is claimed is:

1. A non-volatile NAND Flash memory cell comprising:
a substrate having a first doped materials;
a lightly second doped junction regions near the said substrate surface;
a stacked oxide -nitride-oxide overlaying the second doped surface junction region of the memory cell;
a control gate overlaying a stacked oxide -nitride-oxide of the memory cell; and
a self aligned spacer in the side wall of a control gate over a stacked oxide-nitride-oxide on the substrate of the memory cell in order to isolate the adjacent control gates.

2. The memory cell structure of claim 2 wherein said the first control gate and the self-aligned control gate is formed as polysilicon, or polycide or both combinations of polysilicon and polycide thereon.

3. A string of non-volatile NAND Flash memory cells comprising:
a substrate having a first doped materials;
forming highly second doped source and drain junction regions overlaying the first doped substrate;
forming a first dielectric material on the surface of said the substrate;
forming a selective gates between the second highly doped region on the surface of said the substrate;
forming a second lightly doped junction regions overlaying the said first doped substrate;
forming a control gate overlaying the stacked oxide -nitride-oxide on the substrate;
forming self aligned spacers in the side walls of a control gate on a stacked oxide-nitride-oxide on the substrate; and
forming a secondary dielectric materials between the select gate and the control gates of the memory cell.

4. The string of a NAND memory cells structure of claim 3 wherein said the first dielectric material is oxide or oxy-nitride, or dielectric material.

5. The string of a NAND memory cells structure of claim 3 wherein said the control gate is formed as polysilicon, or polycide or combinations of both polysilicon and polycide thereon.

6. A method making a series of NAND memory cells structure comprising:
forming, through masking steps and ion implantation processes, a first n-well in a semiconductor substrate, forming a first p-well overlaying the first n-well, in a semiconductor substrate;
forming a non-volatile device region by removing either deposited material or materials or grown oxide layer down to surface of the substrate using a mask step;
forming a low doped surface junction for the said non-volatile device region by ion implantation;
forming a first spacer above the body region and adjacent said first polysilicon layer to isolate said memory region;
forming a stacked oxide-nitride-CVD on said the first control gate region;
forming a second polysilicon layer above said the stacked oxide-nitride oxide;
forming a first NAND control gate by etching above said the second polysilicon, and said the stacked oxide-nitride-oxide using mask step processes;
forming a second spacer above the first control gate region and adjacent said the first control gate on the stacked oxide-nitride-oxide;
forming a stacked oxide-nitride-oxide overlaying the entire said substrate;
forming a third polysilicon overlaying the stacked oxide-nitride-oxide overlaying the entire said substrate;
forming a second self-aligned NAND control gate by etch back process for the said entire bodies on the substrate.

7. The method making a series of NAND memory cells structure of claim 6 wherein said the width of the self aligned control gate is determined by the control gate drawn space minus two times the second spacer width;

8. The method making a series of NAND memory cells structure comprising of claim 6 wherein said the width of the self aligned control gate is approximately the same as the width of the first control gate by adjusting the art work drawing in the layout design;

9. The method making a series of NAND memory cells structure comprising of claim 6 wherein said the first, the second and the third polysilicon is doped with in-situ method; and the polysilicon is combination with polycide or silicide;

10. The method making a series of NAND memory cells structure comprising of claim 6 wherein underneath said the second spacer in the region of the NAND cell region is become as the source and drain of the NAND Flash cells said lightly doped during said the ion implantation;

11. The method making a series of NAND memory cells structure comprising of claim 6 wherein underneath said the second spacer in the region of the NAND cell region is become as the source and drain of the NAND Flash cells said lightly doped during said the ion implantation;

12. The memory cell of claim 6 wherein said substrate is a p-type region formed in an n-well.

13. A method making a string of NAND memory cells structure comprising:
forming at least two isolation regions in a semiconductor substrate;
forming, through masking steps and ion implantation processes, a first n-well in a semiconductor substrate, forming a first p-well overlaying the first n-well, forming a second highly doped p-well near the first n-well and the first p-well, forming a second highly doped p-well near the first n-well and the first p-well, forming a second highly doped n-well, and forming a third highly doped n-well regions to define a body region;
forming a first oxide layer or a third oxide layer by using several masking steps above the body region;
forming a first polysilicon layer above said first oxide layer and above said third oxide layer;
forming a non-volatile device region by removing the first polysilicon, the first oxide and the third oxide layer on the substrate using a mask step;
forming a low doped surface junction for the said non-volatile device region by ion implantation;
forming a first spacer above the body region and adjacent said first polysilicon layer;
forming a stacked oxide-nitride-CVD on said the first control gate region;
forming a second polysilicon layer above said the stacked oxide-nitride oxide;
forming a first NAND control gate by etching above said the second polysilicon, and said the stacked oxide-nitride-oxide using mask step processes;
forming a second spacer above the first control gate region and adjacent said the first control gate on the stacked oxide-nitride-oxide;
forming a stacked oxide-nitride-oxide overlaying the entire said substrate;
forming a third polysilicon overlaying the stacked oxide-nitride-oxide overlaying the entire said substrate;
forming a second self-aligned NAND control gate by etch back process for the said entire bodies on the substrate;
forming transistor gates for the low voltages and high voltage over the said the first oxide and the third oxide.

14. The method making a string of NAND memory cells structure of claim 13 wherein said the width of the self aligned control gate is determined by the control gate drawn space minus two times the second spacer width.

15. The method making a string of NAND memory cells structure of claim 13 wherein said the width of the self aligned control gate is approximately the same as the width of the first control gate by adjusting the art work drawing in the layout design.

16. The method making NAND Flash memory comprising string of a NAND memory cells structure of claim 13 wherein said the first, the second and the third polysilicon is doped with in-situ method; and the polysilicon is combination with polycide or silicide.

17. The method making NAND Flash memory comprising string of a NAND memory cells structure of claim 13 wherein underneath said the second spacer in the region of the NAND cell region is become as the source and drain of the NAND Flash cells said lightly doped during said the ion implantation.

18. The memory cell of claim 13 wherein said substrate is a p-type region formed in an n-well.
